(19) United States
(12) Patent Application Publication
(10) Pub. No.: US 2003/0080374 A1
(43) Pub. Date: May 1, 2003

(54) NON-VOLATILE SEMICONDUCTOR MEMORY DEVICE AND MANUFACTURING METHOD THEREOF

(76) Inventor: HAJIME ARAI, HYOGO (JP)

Correspondence Address: MCDERMOTT WILL & EMERY, 600 13TH STREET, N.W., WASHINGTON, DC, 20005-3096, US

(21) Appl. No.: 08/605,566

(22) Filed: Feb. 22, 1996

(30) Foreign Application Priority Data
Jul. 25, 1995 (JP) 7-188871

(51) Int. Cl. H01L 29/788

(52) U.S. Cl. 257/321

(57) ABSTRACT

In a non-volatile semiconductor memory device according to the present invention, an n type impurity introduction conductive layer is formed in a bit line contact hole so as to cover an underlying insulating film exposed to the surface of the bit line contact hole. Formation of the n type impurity introduction conductive layer prevents invasion of impurity ions to a floating gate electrode. As a result, a non-volatile semiconductor memory device with high reliability which prevents the impurity ion entering the non-volatile semiconductor memory device from invading the floating gate electrode and a method for manufacturing the same can be provided.

### BACK GROUND OF THE INVENTION

1. Field of the Invention

The present invention relates to a non-volatile semiconductor memory device and a manufacturing method thereof, and more particularly, to a non-volatile semiconductor memory device having a structure capable of storing electric charge of electrons held in an electric charge storage electrode in a stable state and a method for manufacturing the same.

2. Description of the Background Art

A conventional semiconductor device uses an insulating film material containing n type impurity of phosphorous or the like such as PSG (Phospho Silicate Glass) and BPSG (Boro-Phospho Silicate Glass) as an interlayer insulating film between a gate electrode formed of polysilicon or the like and an interconnection layer formed of metal or the like.

A metal ion such as Na⁺ can move in an oxide film even under a relatively low temperature. Therefore, the metal ion invades a channel region of an MOS transistor, causing device characteristics of the MOS transistor to change.

However, by using the insulating film material containing n type impurity such as PSG and BPSG as a material of an interlayer insulating film as described above, the metal ion such as Na⁺ is trapped by the insulating film material containing n type impurity, and fixed in the interlayer insulating film. As a result, an MOS transistor preventing variation of the device characteristics caused by the alkali metal ion and operating stably can be provided.

Further, in a non-volatile memory cell used in a nonvolatile semiconductor memory device such as an EPROM (Erasable Programmable Read-Only Memory) and a flash memory, data is stored by storing electrons in a floating gate electrode. Therefore, the data must be held in the floating gate electrode for a long period.

When the metal ion or the like invades such a nonvolatile memory cell, the metal ion which is positive electric charge is attracted by an electric field formed by electrons stored in the floating gate electrode, and the metal ions gather in the vicinity of the floating gate electrode. As a result, electric charge of the electrons stored in the floating gate electrode is cancelled. In an extreme case, data stored in the non-volatile memory cell is inverted, leading to defectiveness of the non-volatile memory cell. Therefore, it is extremely important in the non-volatile memory cell to keep a metal ion which is positive electric charge away from the floating gate electrode.

In order to describe problems of the above described conventional non-volatile memory cell, a sectional structure thereof is shown in FIG. 7.

Referring to FIG. 7, n⁺ type impurity regions 2 and 3 are formed in the surface of a p type well 1. The n⁺ type impurity regions 2 and 3 form a pair of source/drain regions.

A tunnel oxide film 4 of a silicon oxide film or the like is formed on a channel region 23 sandwiched by n⁺ type impurity regions 2 and 3. A floating gate electrode 5 formed of a conductive material such as polysilicon and brought to an electrically floating state is formed on tunnel oxide film 4.

A control gate electrode 7 is further formed on floating gate electrode 5 with an insulating film 6 of an oxide film or the like interposed therebetween. Control gate electrode 7 is formed of a conductive material such as polysilicon and polycide and used for controlling injection and ejection of electrons to and from floating gate electrode 5 and for carrying out reading.

A side wall 17 is formed on a side wall of control gate electrode 7 and floating gate electrode 5. An underlying insulating film 8 of an oxide film or the like is further formed so as to cover the surface of p type well 1, floating gate electrode 5, and control gate electrode 7. An interlayer insulating film 9 of a PSG material, a BPSG material or the like is formed on underlying insulating film 8.

As described above, interlayer insulating film 9 is formed of PSG, BPSG or the like. Interlayer insulating film 9 serves to trap a + metal ion. In addition, interlayer insulating film 9 decreases a temperature at which the oxide film is softened by introducing phosphorous, boron or the like into the oxide film to decrease the surface step of interlayer insulating film 9 at a relatively low temperature. As a result, interlayer insulating film 9 brings about an effect of facilitating pattern formation of an interconnection layer 11 to be carried out later. However, interlayer insulating film 9 contains a large amount of impurity such as phosphorous and boron in order to sufficiently planalize the surface of interlayer insulating film 9. Therefore, when interlayer insulating film 9 is in direct contact with p type well 1, impurity such as phosphorous and boron enters in p type well 1 in a thermal treatment for planalizing interlayer insulating film 9.

In order to prevent this, underlying insulating film 8 formed of an oxide film in which impurity is not introduced is formed between interlayer insulating film 9 and p type well 1 (control gate electrode 7).

A bit line contact hole 18 exposing the surface of n⁺ impurity region 3 is provided in interlayer insulating film 9. Interconnection layer 11 of a conductive material such as an aluminum alloy is formed in bit line contact hole 18. Further, as a final protective film of an oxide film, a nitride film or the like, a passivation film 12 is formed so as to cover interlayer insulating film 9 and interconnection layer 11.

A conventional non-volatile memory cell is structured as described above. Therefore, most of metal ions which enter from a defective portion of passivation film 12 are trapped by interlayer insulating film 9. However, at the side surface of contact hole 18, underlying insulating film 8 formed of an oxide film or the like in which n type impurity such as phosphorus is not introduced is exposed (a portion A in FIG. 7).

As a result, referring to FIG. 7, an impurity ion 16 invading from the defective portion of passivation film 12 moves in interconnection layer 11 or an interface between interconnection layer 11 and interlayer insulating film 9. Impurity ion 16 might penetrate underlying insulating film 8 and side wall 17 to reach floating gate electrode 5.

With a recent progress of miniaturization of a nonvolatile memory cell, interconnection layer 11 is formed in bit line contact hole 18 with a barrier metal layer 10 therebetween, as shown in FIG. 8. The distance between the side surface of contact hole 18 and floating gate electrode 5 becomes shorter. As a result, as shown in FIG. 8, the area of underlying insulating film 8 being exposed to the side surface of bit line contact hole 18 gradually increases.

This increases the possibility of impurity ion 16 reaching floating gate electrode 5, which in turn increases the possibility of generation of data storage defectiveness of the non-volatile memory cell.

### SUMMARY OF THE INVENTION

One object of the present invention is to provide a non-volatile semiconductor memory device with high reliability which prevents an impurity ion entering the non-volatile semiconductor memory device from invading a control gate electrode of a non-volatile memory cell, and a method for manufacturing the same.

In order to achieve the above described object, a non-volatile semiconductor memory device according to one aspect of the present invention includes a pair of impurity regions formed on the surface of a semiconductor region of a first conductivity type and having a second conductivity type, an electric charge storage electrode formed on a channel region sandwiched by the pair of impurity regions with a tunnel insulating film interposed therebetween, a control electrode formed on the electric charge storage electrode with an interelectrode insulating film interposed therebetween, an insulating film formed so as to cover the surface of the semiconductor region, the electric charge storage electrode, and the control electrode, an interlayer insulating film having a contact hole exposing the surface of one of the pair of impurity regions and formed so as to cover the insulating film, an impurity introduction conductive layer of the second conductivity type formed in the contact hole so as to cover the insulating film being exposed to an inner surface of the contact hole, and an interconnnection layer electrically connected to the impurity regions in the contact hole.

By providing the impurity introduction conductive layer of the second conductivity-type as described above, the impurity ion invading the interconnection layer or the interface between the interconnection layer and the interlayer insulating film is to be trapped by the impurity introduction conductive layer of the second conductivity type. Therefore, the impurity ion cannot invade the electric charge storage electrode, thereby preventing destruction of electric charge stored in the electric charge storage electrode.

As a result, a non-volatile semiconductor device superior in a data holding characteristic and having high reliability can be provided.

Preferably, the impurity introduction conductive layer of the second conductivity type is formed so as to cover the entire inner surface exposed in the contact hole.

By thus structured, the impurity invading the contact hole is to be trapped by the impurity introduction conductive layer of the second conductivity type. Therefore, even when the non-volatile semiconductor memory device is further miniaturized, and the distance between the inner surface of the contact hole and the electric charge storage electrode is extremely short, the impurity ion is to be trapped by the impurity introduction conductive layer of the second conductivity type.

As a result, a non-volatile semiconductor memory device superior in a data holding characteristic and having high reliability can be provided.

Preferably, the non-volatile semiconductor memory device further includes a barrier metal layer between the impurity introduction conductive layer of the second conductivity type and the inner surface of the contact hole.

By thus structured, an interconnection resistance of the interconnection layer can be decreased when an aluminum alloy or the like is used as the interconnection layer, and reaction between the interconnection layer and the semiconductor region can be prevented with the barrier metal layer.

As a result, even if the non-volatile semiconductor memory device is further miniaturized, the reliability of interconnection of the non-volatile semiconductor memory device can be maintained, making it possible to offer higher performance.

Preferably, a memory cell is formed of the control electrode, the electric charge storage electrode, and the pair of impurity regions, and the non-volatile semiconductor memory device further includes a memory cell array including a plurality of the memory cells arranged in a plurality of rows and columns, a word line provided corresponding to the plurality of rows and to which the control electrode of each memory cell is connected, and a bit line provided corresponding to the plurality of columns and to which one of the pair of impurity regions of each memory cell is connected. The interconnection layer is the bit line.

Therefore, even if a memory cell having a structure according to the present invention is included in an NOR type memory cell array or a DINOR (Divided Bit Line NOR) type memory cell array, a non-volatile semiconductor memory device with high performance superior in a data holding characteristic can be provided.

In order to achieve the above object, a method for manufacturing a non-volatile semiconductor memory device according to another aspect of the present invention includes the following steps.

First, a first insulating film is formed on the main surface of a semiconductor region of a first conductivity type. Then, a first conductive layer is formed on the first insulating film.

Then, a second insulating film is formed on the first conductive layer. After that, a second conductive layer is formed on the second insulating film.

Then, the first insulating film, the first conductive layer, the second insulating film, and the second conductive layer are patterned using a photolithography technique to form a tunnel oxide film, an electric charge storage electrode, an interelectrode insulating film, and a control electrode each having a predetermined shape. Then, with the control electrode used as a mask, impurity of a second conductivity type is introduced in the main surface of the semiconductor region to form a pair of impurity regions of the second conductivity type.

Then, an insulating film is formed so as to cover the semiconductor region, the electric charge storage electrode, and the control electrode. After that, an interlayer insulating layer is formed so as to cover the insulating film.

Then, using the photolithography technique, a contact hole exposing the surface of one of the pair of impurity regions is formed in the interlayer insulating layer.

Then, an impurity introduction conductive layer of the second conductivity type in which impurity of the second conductivity type is introduced is formed in the contact hole so as to cover the insulating film exposed to the inner surface of the contact hole. After that, an interconnection layer electrically connected to the impurity regions is formed in the contact hole.

By providing the impurity introduction conductive layer of the second conductivity type, an impurity ion invading the interconnection layer or the interface between the interconnection layer and the interlayer insulating layer is to be trapped by the impurity introduction conductive layer of the second conductivity type. Therefore, the impurity ion cannot invade the electric charge storage electrode, thereby preventing destruction of electric charge stored in the electric charge storage electrode.

As a result, a non-volatile semiconductor device with high reliability superior in a data holding characteristic can be provided.

Preferably, the impurity introduction conductive layer of the second conductivity type is formed so as to cover all the inner surface exposed in the contact hole.

By thus structured, the impurity invading the contact hole is to be trapped by the impurity introduction conductive layer of the second conductivity type. Therefore, even if the non-volatile semiconductor memory device is further miniaturized, and the distance between the inner surface of the contact hole and the electric charge storage electrode is extremely short, the impurity ion is to be trapped by the impurity introduction conductive layer of the second conductivity type.

As a result, a non-volatile semiconductor memory device with high reliability superior in a data holding characteristic can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a non-volatile semiconductor memory device according to one embodiment of the present invention.

FIGS. 2 to 6 are first to fifth diagrams showing a method for manufacturing the non-volatile semiconductor memory device according to one embodiment of the present invention.

FIGS. 7 and 8 are first and second sectional views showing a structure of a convectional non-volatile semiconductor device.

### DESCRIPTION OF THE PREFERRED EMBODIMENT

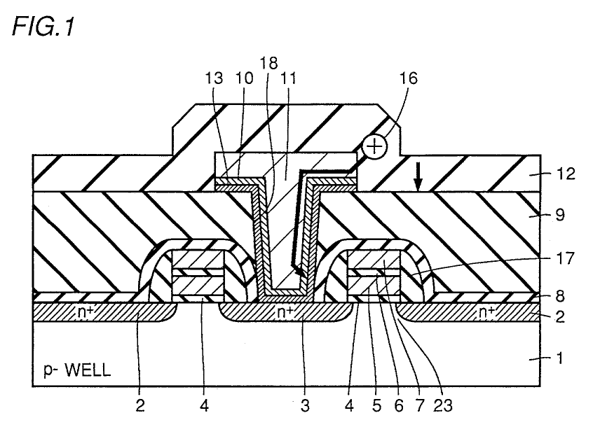

One embodiment of a semiconductor memory device according to the present invention will be described hereinafter with reference to FIG. 1. In FIG. 1, a structure is shown having a feature of the present invention in a bit line contact hole of a non-volatile memory cell included in an NOR type memory cell array, for example.

Referring to FIG. 1, n⁺ type impurity regions 2 and 3 are formed in the surface of p type well 1. The n⁺ type impurity regions 2 and 3 form a pair of source/drain regions.

Tunnel oxide film 4 of a silicon oxide film or the like is formed on channel region 23 sandwiched by n⁺ type impurity regions 2 and 3. Floating gate electrode 5 is formed on tunnel oxide film 4. Floating gate electrode 5 is formed of a conductive material such as polysilicon and brought to an electrically floating state.

Control gate electrode 7 is further formed on floating gate electrode 5 with insulating film 6 of an oxide film or the like interposed therebetween. Control gate electrode 7 is formed of a conductive material such as polysilicon and polycide, and used for controlling injection and ejection of electrons to and from floating gate electrode 5 and for carrying out reading.

Side wall 17 is formed at a side wall of control gate electrode 7 and floating gate electrode 5. Underlying insulating film 8 of an oxide film or the like is further formed so as to cover the surface of p type well 1, floating gate electrode 5, and control gate electrode 7. Interlayer insulating film 9 of a PSG material, a BPSG material or the like is formed on underlying insulating film 8. Note that side wall 17 is formed in order to implement an LDD (Lightly Doped Drain) structure which is employed in order to improve reliability of an MOS transistor in a peripheral circuit portion used for a nonvolatile semiconductor memory device including a nonvolatile memory cell shown in FIG. 1. Therefore, side wall 17 is formed also for the non-volatile memory cell shown in FIG. 1 simultaneously in the manufacturing step of the LDD structure. Side wall 17 is not necessarily required in the non-volatile memory cell shown in FIG. 1. Therefore, there is a case where side wall 17 is not formed.

Bit line contact hole 18 leading to n⁺ drain region 3 is formed in interlayer insulating film 9. In bit line contact hole 18, an n⁺ impurity introduction conductive layer 13 is formed so as to cover the inner surface of bit line contact hole 18.

Barrier metal layer 10 of titanium, tungsten, or tantalum titanium nitride is formed on impurity introduction conductive layer 13. A bit line 11 using an aluminum alloy or a copper system alloy is formed on barrier metal layer 10.

Barrier metal layer 10 is provided in order to prevent reaction between n type impurity introduction conductive layer 13 and bit line 11 when n type impurity introduction conductive layer 13 and bit line 11 formed of an aluminum alloy or the like are in a direct contact with each other. Therefore, if a material which does not react with n type impurity introduction conductive layer 13 is used as a material for bit line 11, it is not necessary to provide barrier metal layer 10.

As described above, by providing n type impurity introduction conductive layer 13 in bit line contact hole 18 so as to cover the inner surface of bit line contact hole 18, underlying insulating film 8 exposed to the inner surface of bit line contact hole 18 can be covered with n type impurity introduction conductive layer 13.

As a result, as shown in FIG. 1, impurity ion 16 invading from a defective portion or the like of passivation film 12 is to be trapped by n type impurity introduction conductive layer 13, which in turn prevents invasion of impurity ion 16 to floating gate electrode 5 and destruction of electric charge stored in floating gate electrode 5.

As a result, a non-volatile semiconductor memory device including a memory cell with high reliability superior in a data holding characteristic can be provided.

Note that in the semiconductor device shown in FIG. 1, the n type impurity introduction conductive layer is provided so as to cover the entire inner surface of bit line contact hole 18. However, the present invention is not limited to this structure. The similar effect can be obtained by covering with n type impurity introduction conductive layer 13 only a portion of bit line contact hole 18 to which underlying insulating film 8 is exposed, for example.

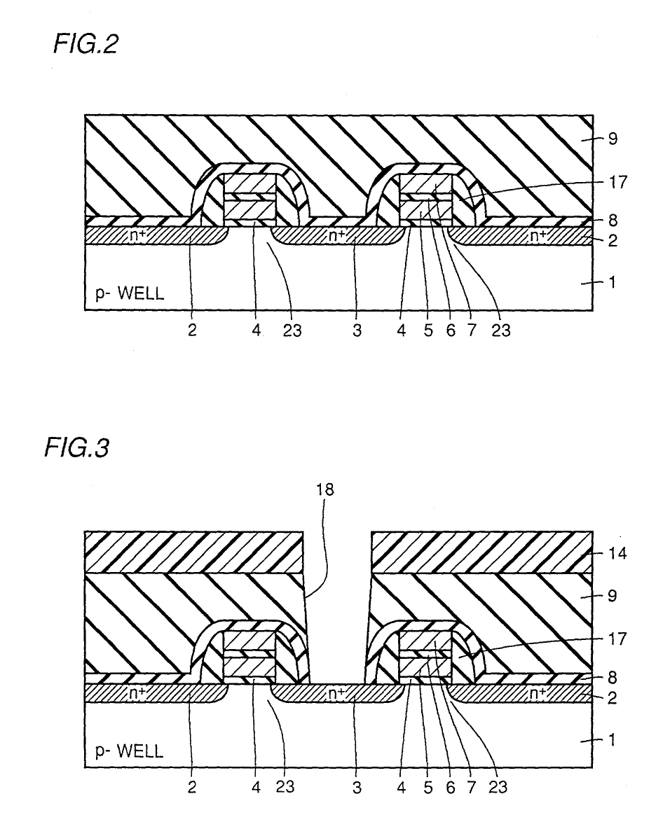

A method for manufacturing the above described nonvolatile semiconductor memory device will now be described with reference FIGS. 2 to 6.

Referring to FIG. 2, a first insulating film is formed on the main surface of p type well 1. Then, a first conductive layer of polysilicon, polycide or the like is formed on the first insulating film. Then, a second insulating film of an oxide film or the like is formed on the first conductive layer. After that, a second conductive layer of polysilicon, polycide or the like is formed on the second insulating film.

Then, the first insulating film, the first conductive layer, the second insulating film, and the second conductive layer are patterned using a photolithography technique, to form tunnel oxide film 4, floating gate electrode 5, interelectrode insulating film 6, and control gate electrode 7 each having a predetermined shape.

Then, with control gate electrode 7 used as a mask, n type impurity is introduced in the main surface of p type well 1 to form n⁺ type source region 2 and n⁺ type drain region 3. After that, side wall 17 of oxide silicon or the like is formed at a side surface of control gate electrode 7 and floating gate electrode 5. Note that side wall 17 is formed also in a memory cell region when an LDD structure which is employed for improving reliability of an MOS transistor is formed in a peripheral circuit portion (not shown). Side wall 17 is not required particularly for operation of this memory cell. Therefore, there may be a case where side wall 17 is not formed.

Then, underlying insulating film 8 of an oxide film or the like is formed with a CVD method so as to cover p type well 1 and floating gate electrode 5. After that, interlayer insulating film 9 of PSG, BPSG or the like is formed with the CVD method or the like so as to cover underlying insulating film 8. The surface of interlayer insulating film 9 is planarized by being subjected to a predetermined heat treatment.

Referring to FIG. 3, a resist film 14 having an opening portion of a predetermined shape is formed on interlayer insulating film 9 using a photolithography technique. Then, with resist film 14 used as a mask, interlayer insulating film 9 is etched so that bit line contact hole 18 having a diameter of approximately 1.0 μm or less which exposes the surface of n⁺ type drain region 3 is formed.

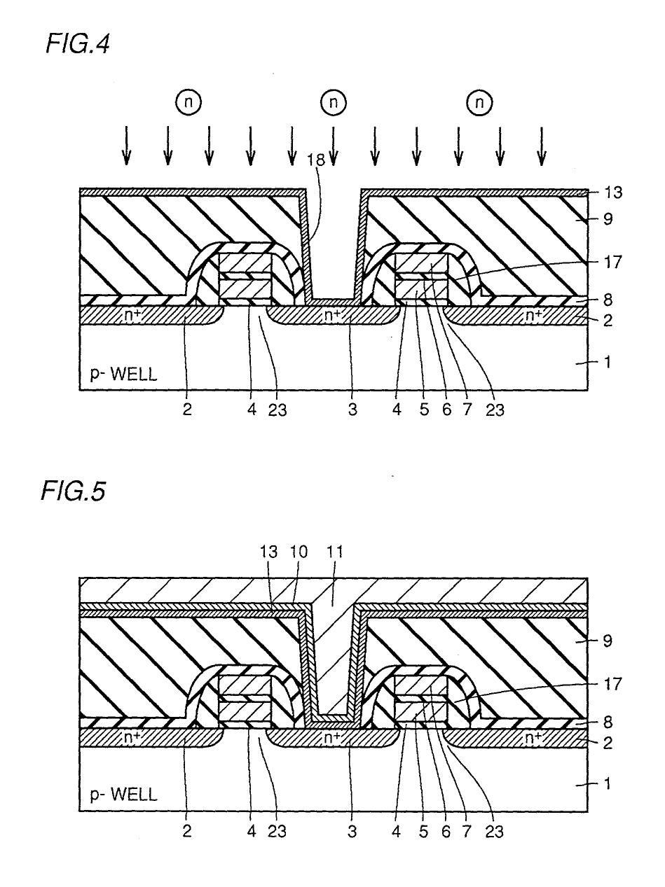

Then, referring to FIG. 4, after removing resist film 14, a polysilicon film is deposited approximately 0.1 to 0.2 μm in thickness so as to cover the surface of interlayer insulating film 9 and the inner surface of bit line contact hole 18 with the CVD method or the like. Then, n type impurity such as phosphorous is introduced in the polysilicon film under the conditions of implantation energy of 30 to 100 keV and an implantation amount of 5×10¹² cm⁻² to 1×10¹⁵ cm⁻², and the polysilicon film is subjected to a heat treatment at a temperature of 900° C. or less to form n type impurity introduction conductive layer 13.

Referring to FIG. 5, barrier metal layer 10 using titanium, tungsten, or tantalum titanium nitride is deposited approximately 0.05 to 0.15 μm in thickness on n type impurity introduction conductive layer 13. Further, bit line 11 using an aluminum alloy or a copper system alloy is deposited approximately 0.3 to 1.0 μm in thickness on barrier metal layer 10 with the CVD method.

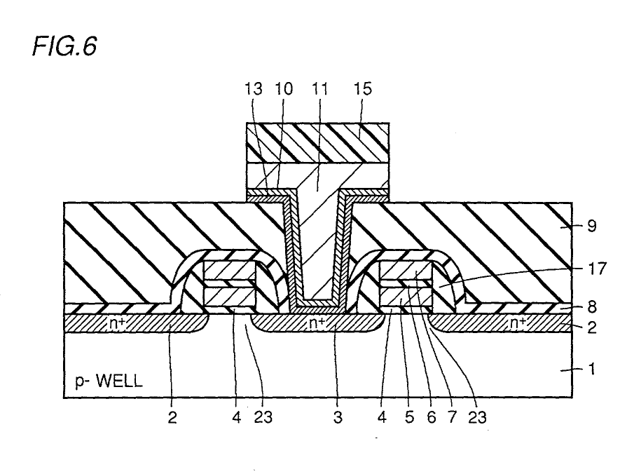

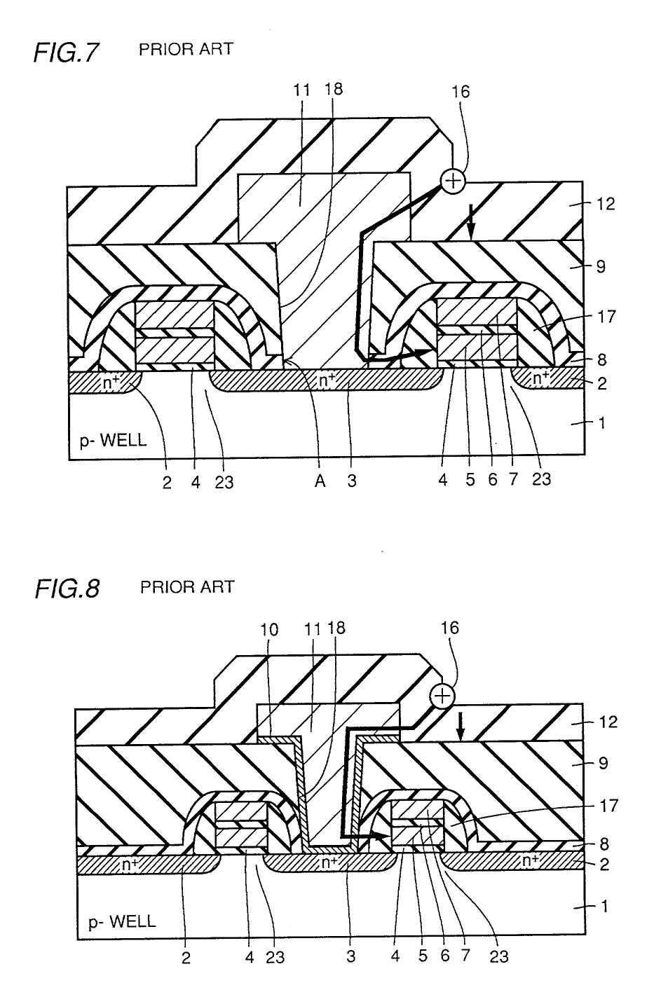

Then, referring to FIG. 6, a resist film 15 having a predetermined pattern is formed on bit line 11 with a photolithography technique. After that, with resist film 15 used as a mask, bit line 11, barrier metal layer 10, and n type impurity introduction conductive layer 13 are patterned.

By removing resist film 15, the semiconductor device shown in FIG. 1 is completed.

In the step of implanting the n type impurity to the side wall of bit line contact hole 18 of a polysilicon layer shown in FIG. 4, an oblique rotation ion implantation method is employed in which the impurity is implanted slightly obliquely to p type well 1 while rotating p type well 1. By employing this method, impurity ions can be implanted more effectively also to the polysilicon film near the bottom portion of bit line contact hole 18.

As compared to a conventional method for manufacturing a non-volatile semiconductor device, the method for manufacturing the non-volatile semiconductor device according to the present embodiment can provide easily a non-volatile semiconductor device with high reliability only by increasing the step of forming n type impurity introduction conductive layer 13.

In the above described embodiment, an n channel type memory cell is used for p type well 1, and the n type impurity introduction conductive layer is provided. However, the present invention is not limited thereto. By using a p channel type memory cell for an n type well and providing a p type impurity introduction conductive layer, the similar effect can be obtained.

In the above embodiment, the case was described where a bit line is used as an interconnection layer. However, the present invention is not limited to the bit line. In the other interconnection layers which have such an interconnection structure as shown in FIG. 1 for a nonvolatile memory cell, the similar effect can be obtained by provision of an impurity introduction conductive layer as shown in the present embodiment.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A non-volatile semiconductor memory device, comprising:
a pair of impurity regions formed in a surface of a semiconductor region of a first conductivity type and having a second conductivity type;
an electric charge storage electrode formed on a channel region sandwiched by said pair of impurity regions with a tunnel insulating film interposed therebetween;
a control electrode formed on said electric charge storage electrode with an interelectrode insulating film interposed therebetween;
an insulating film formed so as to cover a surface of said semiconductor region, said electric charge storage electrode, and said control electrode;
an interlayer insulting layer having a contact hole exposing a surface of one of said pair of impurity regions and formed so as to cover said insulating film;
an impurity introduction conductive layer of the second conductivity type formed in said contact hole so as to cover said insulating film exposed to an inner surface of said contact hole; and
an interconnection layer electrically connected to said impurity regions in said contact hole.

2. The non-volatile semiconductor memory device according to claim 1, wherein
said impurity introduction conductive layer of the second conductivity type is formed so as to cover all the inner surface exposed in said contact hole.

3. The non-volatile semiconductor memory device according to claim 2, further comprising
a barrier metal layer formed between said impurity introduction conductive layer of the second conductivity type and the inner surface of said contact hole.

4. The non-volatile semiconductor memory device according to claim 1, wherein
a memory cell is formed of said control electrode, said electric charge storage electrode, and said pair of impurity regions,
said non-volatile semiconductor memory device includes
a memory cell array having a plurality of said memory cells arranged in a plurality of rows and columns,
a word line provided corresponding to said plurality of rows and to which the control electrode of said each memory cell is connected, and
a bit line provided corresponding to said plurality of columns and to which one of said pair of impurity regions of said each memory cell is connected, and
said interconnection layer is said bit line.

5. A method for manufacturing a non-volatile semiconductor memory device, comprising the steps of:
forming a first insulating film on a main surface of a semiconductor region of a first conductivity type;
forming a first conductive layer on said first insulating film;
forming a second insulating film on said first conductive layer;
forming a second conductive layer on said second insulating film;
patterning said first insulating film, said first conductive layer, said second insulating film, and said second conductive layer with a photolithography technique to form a tunnel oxide film, an electric charge storage electrode, an interelectrode insulating film, and a control electrode each having a predetermined shape;
introducing impurity of a second conductivity type to the main surface of said semiconductor region with said control electrode used as a mask to form a pair of impurity regions of the second conductivity;
forming an insulating film so as to cover said semiconductor region, said electric charge storage electrode, and said control electrode;
forming an interlayer insulating layer so as to cover said insulating film;
forming a contact hole exposing a surface of one of said pair of impurity regions in said interlayer insulating layer with the photolithography technique;
forming in said contact hole an impurity introduction conductive layer of the second conductivity type to which impurity of the second conductivity type is introduced so as to cover said insulating film exposed to an inner surface of said contact hole; and
forming an interconnection layer electrically connected to said impurity regions in said contact hole.

6. The method for manufacturing a non-volatile semiconductor memory device according to claim 6, wherein
said step of forming said impurity introduction conductive layer of the second conductivity type includes the step of forming said impurity introduction conductive layer so as to cover all the inner surface exposed in said contact hole.
